(19) United States
(12) Patent Application Publication
(10) Pub. No.: US 2023/0231066 A1
(43) Pub. Date: Jul. 20, 2023

(54) PHOTOVOLTAIC CELLS WITH WAVELENGTH-SELECTIVE LIGHT TRAPPING

(71) Applicants: Nicholas P. Irvin, Phoenix, AZ (US); Richard R. King, Tempe, AZ (US); Christiana Honsberg, Tempe, AZ (US); Chaomin Zhang, Tempe, AZ (US)

(72) Inventors: Nicholas P. Irvin, Phoenix, AZ (US); Richard R. King, Tempe, AZ (US); Christiana Honsberg, Tempe, AZ (US); Chaomin Zhang, Tempe, AZ (US)

(21) Appl. No.: 18/154,723

(22) Filed: Jan. 13, 2023

Related U.S. Application Data
(60) Provisional application No. 63/299,821, filed on Jan. 14, 2022.

(51) Int. Cl. H01L 31/054; H01L 31/052

(52) U.S. Cl. CPC H01L 31/0543; H01L 31/052

(57) ABSTRACT

A photovoltaic cell includes a front layer, a rear layer, and an absorber layer between the front layer and the rear layer. The front layer, the rear layer, or both includes a multiplicity of nanostructures having dimensions in a range of about 1 nm to about 1000 nm.

### CROSS-REFERENCE TO RELATED APPLICATION

This application claims the benefit of U.S. Patent Application 63/299,821 filed on Jan. 14, 2022, which is incorporated herein by reference in its entirety.

### TECHNICAL FIELD

This invention relates to photovoltaic cells with nanostructures configured for wavelength-selective light trapping, as well as methods of making the photovoltaic cells.

### BACKGROUND

Photovoltaic (PV) cells typically include semiconductor absorber layers, with III-V, II-VI, perovskite, silicon, germanium, SiGe, or other semiconductor materials. These absorber layers absorb light with photon energy above their bandgap energy to generate electron-hole pairs. The absorber layers can also exhibit non-radiative recombination in the bulk of the absorber material such as trap-assisted recombination or Auger recombination. If the surfaces of a photovoltaic cell have been passivated (e.g., treated so that the surface recombination rate of electrons and holes is low) then the photovoltaic cell will tend to exhibit higher voltage as the absorber thickness is reduced, since this lowers the volume of material in which bulk recombination can take place, reducing the overall recombination rate in the cell, increasing the excess carrier concentration, quasi-Fermi level splitting, and cell voltage that can be supported for a given incident photon flux. The absorber semiconductor materials can also be expensive and time-consuming to grow, such that thicker layers add cost to the manufacture of the photovoltaic cell. Thinner absorber layers can also increase the flexibility of photovoltaic cells. However, thinner absorber layers also mean that there is less semiconductor volume available for light absorption to create electron-hole pairs, tending to reduce the photogenerated current density and efficiency of the photovoltaic cell.

### SUMMARY

This disclosure describes photovoltaic cells with nanostructures configured for wavelength-selective light trapping, as well as methods of making the photovoltaic cells. The nanostructures deflect light that is incident upon, emitted by, or reflected by the photovoltaic cell into a range of propagation angles. This range of propagation angles promotes light trapping and optical path length enhancement, leading to greater photogeneration of electron and hole charge carriers and corresponding photocurrent production in the photovoltaic cell. The nanostructures allow the use of thinner semiconductor absorber layers that operate with reduced recombination and heat generation to more efficiently convert monochromatic light into electricity.

In a first general aspect, a photovoltaic cell includes a front layer, a rear layer, and an absorber layer between the front layer and the rear layer. The front layer, the rear layer, or both include a multiplicity of nanostructures having dimensions in a range of about 1 nm to about 1000 nm.

Implementations of the first general aspect can include one or more of the following features.

In some cases, an outer surface of the front layer includes the multiplicity of nanostructures. The multiplicity of nanostructures can be embedded in a material having an index of refraction that differs from an index of refraction of the nanostructures. In some implementations, the multiplicity of nanostructures is in a shape of cones, pyramids, bars, crosses, or any combination thereof. In some cases, a spacing between the multiplicity of nanostructures is uniform. In some implementations, the multiplicity of nanostructures is arranged in a periodic 1-, 2-, or 3-dimensional array. The multiplicity of nanostructures can be configured to refract, reflect, or diffract incident light into a range of propagation angles to alter light trapping, optical path length, photogeneration of electron and hole charge carriers, and photocurrent production in the photovoltaic cell. In some cases, a spacing between the multiplicity of nanostructures is less than a wavelength of light to be diffracted by the nanostructures. In some implementations, a size of the multiplicity of nanostructures is less than a wavelength of light to be diffracted by the multiplicity of nanostructures.

In some cases, the multiplicity of nanostructures includes amorphous silicon (a-Si), GaAs, AlInP, AlGaAs, GaInP, InGaAs, Ge, Si, AlP, InN, ZnO, GaP, CdSe, ZnTe, SiC (amorphous or crystalline), TiO₂, CdTe. The multiplicity of nanostructures can include a perovskite. In some implementations, the perovskite includes CH₃NH₃Pb(Cl, Br,I)₃. The multiplicity of nanostructures can include GaN, ZnSe, ZnS, CdS, Ta2O5, Al₂O₃, AlN, MgO, ZnCdO, ITO, SU-8, SiNₓ, SiO₂, or MgF₂. In some cases, the multiplicity of nanostructures includes an organic semiconductor. In some implementations, the organic semiconductor includes C₂₂H₁₄. In some implementations, the multiplicity of nanostructures includes an organic polymer. The organic polymer can include poly(methyl methacrylate) or PEDOT:PSS.

In some cases, the multiplicity of nanostructures includes a diffractive grating. The rear layer can be a reflective layer. In some implementations, the first general aspect further includes an angular selective filter on the front layer. In some cases, a device includes the first general aspect. The multiplicity of nanostructures can be configured to minimally refract, reflect, or diffract incident light having wavelengths with a photon energy below a bandgap energy of the photovoltaic cell. In some cases, the incident light is infrared light. In some implementations, the first general aspect further includes a multiplicity of microstructures configured to couple infrared light into and out of the photovoltaic cell, wherein the microstructures have dimensions in a range of about 0.7 um to about 1000 um.

Wavelength-selective light trapping provides various advantages, such as reduced heat generation in thermophotovoltaic cells, greater radiative cooling with infrared emission, and extreme light trapping for photonic power converters (PPC), resulting in increased device efficiency. The gains can be especially pronounced for lower-lifetime material.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A is a cross-sectional view of a schematic of a photovoltaic cell with a front layer that includes nanostructures and a reflective rear layer with a textured inner surface. FIG. 1B is a cross-sectional view of a schematic of a photovoltaic cell with an angular selective filter as a front layer and a reflective rear layer.

FIG. 2A shows an enlarged cross-sectional view of a portion of a photovoltaic cell with a front layer that includes a portion of a conical nanostructure. FIG. 2B shows a wide view of the photovoltaic cell of FIG. 2A.

FIGS. 3A-3C show the short-circuit current density J_{sc} and the open circuit voltage V_{oc}, respectively, as a function of absorber width for a series of path-length enhancement values.

FIG. 4 shows the percent efficiency as a function of laser wavelength for a series of path-length enhancement values.

### DETAILED DESCRIPTION

This disclosure describes photovoltaic (PV) cells with nanostructures configured for wavelength-selective light trapping, as well as methods of making the photovoltaic cells. Nanostructures included on the front layer, the rear layer, or both layers of the photovoltaic cell can produce a path-length enhancement for light incident upon, emitted by, or reflected by the PV cell. This path-length enhancement can produce an increased light absorption by an absorber layer positioned between the front and rear layers, thereby increasing the efficiency of the PV cell.

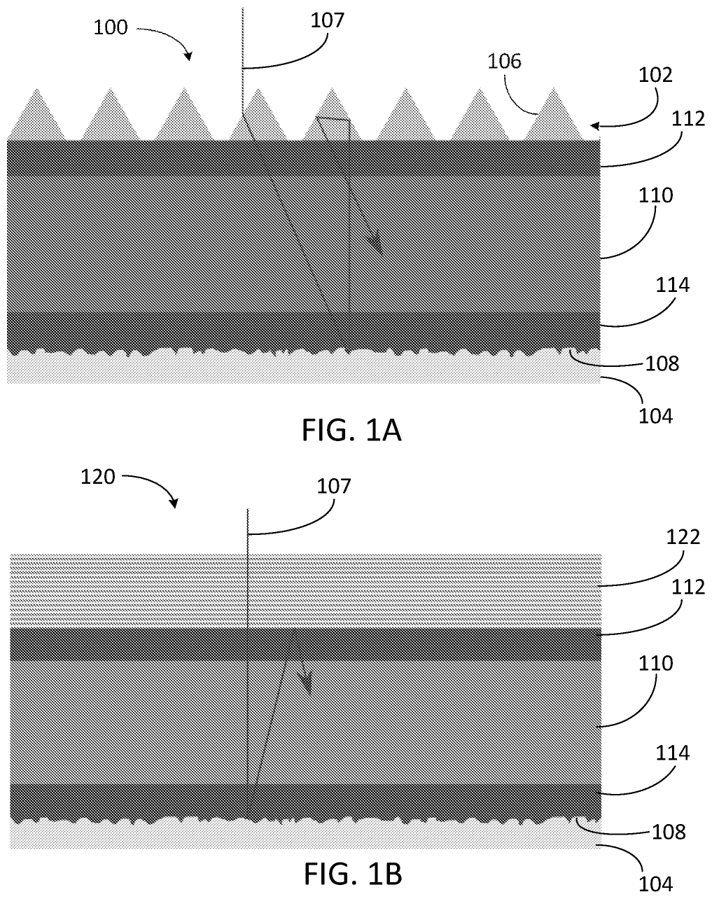

FIG. 1A is a cross-sectional view of a schematic of photovoltaic cell 100 with front layer 102 and rear layer 104. Front layer 102 includes a multiplicity of nanostructures 106. Nanostructures 106 can be arranged in an array. Nanostructures 106 in front layer 102 are configured to trap light 107 of selected wavelengths in photovoltaic cell 100. Rear layer 104 is a reflective layer with textured inner surface 108. Absorber layer 110 is a p-type layer between front layer 102 and rear layer 104. n-type layer 112 is between front layer 102 and absorber layer 110. p-type back surface field 114 is between rear layer 104 and absorber layer 110.

In FIG. 1A, nanostructures 106 are depicted in front layer 102. However, photovoltaic cell 100 can have nanostructures in front layer 102, rear layer 104, or both. In FIG. 1A, nanostructures 106 are depicted as having a cone shape. However, nanostructures can have a variety of other shapes, sizes, spacings, multiplicities, or any combination thereof, as described herein.

FIG. 1B is a cross-sectional view of a schematic of photovoltaic cell 120 with a front layer that includes an angular selective filter 122. The embodiment depicted in FIG. 1B can yield a path-length enhancement of 1200x. In another embodiment, an angular selective filter 122 is combined with a rear diffractive grating.

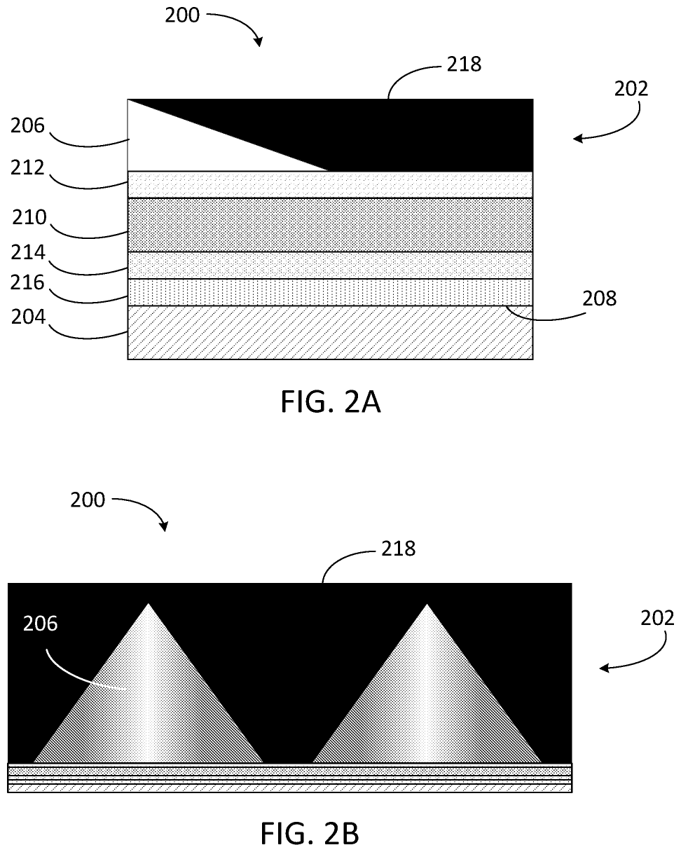

FIG. 2A shows an enlarged cross-sectional view of a portion of photovoltaic cell 200 with front layer 202 that includes a portion of nanostructure 206 having a cone shape. Absorber layer 210 is a p-type layer between front layer 202 and rear layer 204. Rear layer 204 is a reflective layer that is depicted in FIG. 2A as having a smooth inner surface 208, but can have a textured inner surface. n-type layer 212 is between front layer 202 and absorber layer 210. p-type back surface field 214 is between rear layer 204 and absorber layer 210. Layer 216 is between p-type back surface field 214 and rear layer 204. Nanostructure 206 in front layer 202 is embedded in material 218 having an index of refraction that differs from the index of refraction of the nanostructure 206. FIG. 2B shows a wide view of the photovoltaic cell 200 depicted in FIG. 2A. Nanostructures 206 are embedded in material 218 included in front layer 202.

Nanostructures can have a general 1-dimensional, 2-dimensional, or 3-dimensional shape. Dimensions of nanostructures are typically in a range of about 1 nm to about 1000 nm (e.g., about 1 nm to about 800 nm, or about 50 nm to about 500 nm), and can be configured to interact with light that is incident upon, emitted by, or reflected by the photovoltaic cell. “Dimensions” refers to structural features of the nanostructures as disclosed herein (e.g., base diameter, height, length, lateral dimension, lateral width, and lateral length).

Nanostructures can be positioned randomly or in 1-, 2-, or 3-dimensional periodic arrays or combination of periodic arrays. In an array or multiplicity of nanostructures, the general feature shape can have any orientation with respect to the line between the center-of-mass points of adjacent features in the array. In an array of nanostructures, the array can have the same center-to-center spacing between all adjacent features, or can have different center-to-center spacings between adjacent features, where center-to-center spacing is defined as the physical distance between the center-of-mass points of adjacent nanostructures.

As depicted in FIG. 1A, nanostructures 106 are cones having an approximately triangular cross section through the axis of symmetry, with base diameters and vertex angles selected to control deflection of incident light by diffraction from the features and maximize performance of photovoltaic cell 100. Other shapes are described herein.

In some embodiments, nanostructures 106 are truncated nanocones with an approximately trapezoidal cross section through the axis of symmetry, with base diameter, height, and sidewall angles that can be varied to control deflection of incident light by diffraction from the features and maximize performance of the photovoltaic cell.

In some embodiments, nanostructures 106 are nanopyramids with an approximately triangular cross section through the center axis, with base width, height, and sidewall angles which may be varied to control deflection of incident light by diffraction from the features and maximize performance of the photovoltaic cell.

In some embodiments, nanostructures 106 are truncated nanopyramids with an approximately trapezoidal cross section through the center axis, with base width, height, and sidewall angles (including the possibility of vertical or overhanging sidewalls) which can be varied to control deflection of incident light by diffraction from the features and maximize performance of the photovoltaic cell.

In some embodiments, nanostructures 106 are nanobars with spatial extent (e.g., length) in a first lateral dimension greater than the spatial extent (e.g., width) length in a second lateral dimension that is perpendicular to the first dimension (typically by a ratio in the range of 1.2:1 to 20:1). The nanostructure can have an approximately trapezoidal vertical cross section through the nanobar. Base length in the first lateral dimension, base width in the second lateral dimension, height, and sidewall angles (including the possibility of vertical or overhanging sidewalls) can each be varied to control deflection of incident light by diffraction from the features to maximize performance of the photovoltaic cell. In an array of nanobars, the angle between the long axis of the nanobar and a line between the midpoints of adjacent nanobars in the array can be in the range of 0 to 180 degrees.

In some embodiments, nanostructures 106 are nanocrosses. The nanocrosses can have the shape of two intersecting nanobars. The two intersecting nanobars can have the same lateral length along their respective long axes, or these lengths can be different. The two intersecting nanobars can have the same lateral width along their respective short axes, or these widths can be different. The two intersecting nanobars can intersect at their midpoints, or at another point along their lengths. The angle between the long axes of the two intersecting nanobars that form the nanocross can be perpendicular (90 degrees), or can be in the range between 0 and 180 degrees. The base lengths along the long axes, base widths along the short axes, the sidewall angles, and the angle between the long axes of the two nanobars that form each nanocross can be varied to control deflection of incident light by diffraction from the features to maximize performance of the photovoltaic cell. In an array of nanocrosses, the angle between the long axis of either of the two nanobars that form a nanocross, and the line between the intersection point of the two nanobars which form an adjacent nanocross in the array, can be in the range of 0 to 180 degrees.

The nanostructures can be implemented using a wide range of materials, including: amorphous silicon (a-Si), GaAs, AlInP, AlGaAs, GaInP, InGaAs, Ge, Si, AlP, InN, ZnO, GaP, CdSe, ZnTe, SiC (amorphous or crystalline), TiO₂, CdTe, and perovskites including CH₃NH₃Pb(Cl, Br,I)₃; lower index materials such as GaN, ZnSe, ZnS, CdS, Ta₂O₅, Al₂O₃, AlN, MgO, ZnCdO, ITO, SU-8, SiNₓ, SiO₂, MgF₂; organic semiconductors including C₂₂H₁₄ and organic polymers including poly(methyl methacrylate) and PEDOT:PSS.

In some embodiments, the nanostructures are in contact with a vacuum. Referring to FIGS. 2A and 2B, in some embodiments, the nanostructures 206 are in contact with (e.g., at least partially surrounded by, embedded by, or coated with) a material 218 that has a different (e.g., lower) refractive index than the nanostructures 206 to form a refractive index contrast. The material 218 can be any material described herein with respect to the nanostructures (e.g., a semiconductor, a transparent conductive oxide, a transparent polymer, a dielectric such as SiO₂ or MgF₂).

In some embodiments, the nanostructures are formed by lithography methods. Suitable lithography methods include imprint lithography (e.g., nanoimprint lithography), self-assembly lithography (e.g., nanosphere lithography), photolithography, electron-beam lithography, X-ray lithography, scanning probe lithography, holographic lithography, and shadow mask fabrication. In some embodiments the nanostructures are formed by molecular gate based patterning, high resolution inkjet printing, and letter press at the nano- or micrometer-scale.

In some embodiments, nanostructures are configured to deflect light by refraction and reflection, which are the predominant light trapping mechanisms when nanostructure features are larger than the light wavelength (e.g., as depicted in ray-tracing models). Refraction and reflection can be combined with deflection of light by diffraction (e.g., as depicted in electromagnetic wave models). Diffraction becomes stronger for nanostructure feature sizes and spacings on the order of, or smaller than, the light wavelengths.

In some embodiments, nanostructures modify the light incident on or escaping from the front surface of the photovoltaic cell, or the light incident on or escaping from the back surface of the photovoltaic cell. The light escaping from the surfaces may be transmitted or reflected incident light, or may be light emitted by radiative recombination of electrons and holes in the photovoltaic cell.

In some embodiments, nanostructures interact with light through a refractive index contrast between the features and the surrounding material.

In some embodiments, nanostructures deflect incident light into a range of propagation angles, which promote greater light trapping, optical path length, photogeneration of electron and hole charge carriers, and photocurrent production in the photovoltaic cell.

In some embodiments, nanostructures deflect incoming light by diffraction of light by the collective effect of an array of two or more nanostructures, or by diffraction of light by individual features in isolation from neighboring features. For diffraction from an array of features the spacing of the features is typically on the order of, or smaller than, the wavelengths of light to be diffracted. The size of the features may be on the order of, or smaller than, the wavelengths of light to be diffracted. For diffraction from multiple individual features, the size of the features is typically on the order of, or smaller than the wavelengths of light to be diffracted, and the spacing of the features is typically larger than the wavelengths to be diffracted.

In some embodiments, the photovoltaic cell includes microstructures configured to couple infrared light into and out of the photovoltaic cell. Such wavelength-selective light trapping leads to thermal benefits from enhanced radiative cooling. The microstructures have dimensions in a range of about 0.7 μm to about 1000 μm.

For applications with more than one wavelength of light incident on a photovoltaic cell, nanostructures can be configured to diffract short wavelengths of light at large angles with respect to the surface normal, promoting light trapping, and greater photoabsorption and photocurrent in the photovoltaic cell. In some embodiments, the nanostructures are designed to have a smaller diffractive effect or to diffract light at smaller angles with respect to the surface normal for longer wavelengths of light, such that these longer wavelengths of light have a greater specular component of reflection than the shorter wavelengths. This configuration can reduce light trapping and increase the power of incident light reflected away from the cell at long wavelengths, reducing unnecessary photovoltaic cell heating.

In thermophotovoltaic (TPV) cell embodiments, a configuration that promotes less diffraction at longer wavelengths and greater diffraction at shorter wavelengths as described above can increase the amount of longer wavelength incident light reflected back to the thermal emitter to be reabsorbed as useful energy by the emitter. For example, if the short wavelengths are at a photon energy greater than the bandgap energy of the photovoltaic cell, greater diffraction, light trapping, and photoabsorption of the short wavelengths can increase the rate of electron-hole pair generation in the photovoltaic cell, thereby increasing the efficiency of energy conversion. If the longer wavelengths are at a photon energy less than the bandgap energy of the photovoltaic cell, greater specular reflection, and reduced light trapping and parasitic absorption of the longer wavelengths, can reduce the amount of photovoltaic cell heating by wavelengths that are not needed for photogeneration, thereby lowering the cell temperature and increasing the cell voltage and efficiency of the photovoltaic cell. Greater specular reflection and reduced light trapping of the longer wavelengths can increase the power produced by otherwise unused sub-band gap light returned to the thermal radiator that powers the TPV cell, and increase the amount of unused light that is recycled by reheating the thermal radiator, thereby increasing the overall system energy conversion efficiency.

The nanostructures can be implemented on photovoltaic cells with a wide range of absorber materials, including those described with respect to the nanostructures, such as amorphous silicon (a-Si), GaAs, AlInP, AlGaAs, InGaAs, GaInP, Ge, Si, AlP, InN, ZnCdO, GaP, CdSe, ZnTe, SiC (amorphous or crystalline), CdTe, GaN, ZnSe, ZnS, CdS, AlN, organic semiconductors like C₂₂H₁₄, and perovskites such as CH₃NH₃Pb(Cl, Br,I)₃. Without light trapping, a thickness of the absorber layer for a thin film can typically range from about 300 nm to about 5000 nm. With light trapping, a typical thickness can be reduced by an order of magnitude or more (e.g., about 30 nm to about 500 nm).

Referring to FIG. 2A, n-type layer 212 can be composed of GaInP. A thickness of layer 212 is typically in a range of about 10 nm to about 100 nm. In one example, p-type back surface field 214 is composed of GaInP. A thickness of p-type back surface field 214 is typically in a range of about 10 nm to about 100 nm. In one example, layer 216 is composed of AlGaAs. A thickness of layer 216 is typically in a range of about 10 nm to about 100 nm. The rear layer 204 is a reflective layer. In one example, rear layer 204 is composed of Ag. A thickness of rear layer 204 is typically in a range of about 50 nm to about 1 μm. The rear layer 204 can be smooth or textured. The rear layer 204 can include nanostructures as described herein.

The nanostructures can be implemented on photovoltaic cells for a wide range of applications, including: photonic power converters (PPCs) designed primarily to convert monochromatic light to electrical power; solar cells for earth-based electrical power generation from non-concentrated sunlight; solar cells for earth-based electrical power generation from concentrated sunlight; solar cells for outer space-based electrical power generation from non-concentrated sunlight; solar cells for outer space-based electrical power generation from concentrated sunlight; thermophotovoltaic (TPV) cells for conversion of light radiated by a thermal emitter to electrical power; and other types of photovoltaic cells.

Photonic power converters (PPC) convert monochromatic light into electricity through photovoltaics (PV). In order to benchmark the benefits of absorption enhancement, PPC efficiency is modeled as a function of path-length enhancement. The amplitude of the left-incident wave is found as

$${A}_{-} = \frac{α}{{α}_{t}} \frac{\frac{X}{2} α ϕ}{1 - ( 1 - \frac{4}{X} ) {e}^{- X α W}} , \qquad ( 1 )$$

where X is the path-length enhancement, a is the band-to-band absorption coefficient, αₜ is the sum of α and free-carrier absorption (FCA), and W is the absorber thickness.

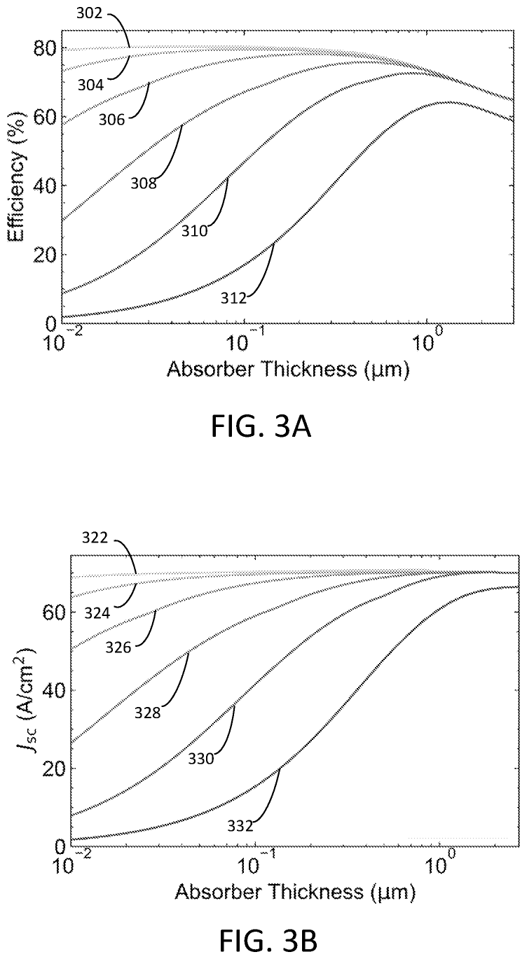

The PPC efficiency as a function of absorber thickness for different path-length enhancement values X is shown in FIG. 3A. Curves 302, 304, 306, 308, 310, and 312 correspond to path-length enhancement values X of 6000, 1200, 250, 50, 10, and 2 respectively. The modeled absorber is an n-GaAs with 2.10¹⁷ cm⁻³ doping and 10 ns bulk trap-assisted lifetime, which are characteristic of the material grown with molecular beam epitaxy. The contact layers are considered to be carrier-selective contacts with an ideal front contact but a rear surface recombination velocity of 3600 cm/s. FIG. 3B shows the short-circuit current density J_{sc}, as a function of absorber thickness for different values of path-length enhancement X. Curves 322, 324, 326, 328, 330, and 332 correspond to path-length enhancement values X of 6000, 1200, 250, 50, 10, and 2 respectively. FIG. 3C shows the open circuit voltage V_{oc} as a function of absorber thickness for different values of path-length enhancement X. Curves 342, 344, 346, 348, 350, and 352 correspond to path-length enhancement values X of 6000, 1200, 250, 50, 10, and 2 respectively. For the low-lifetime material modeled, light trapping increases absorption and J_{sc} while enabling thinning of the absorber to increase V_{oc}.

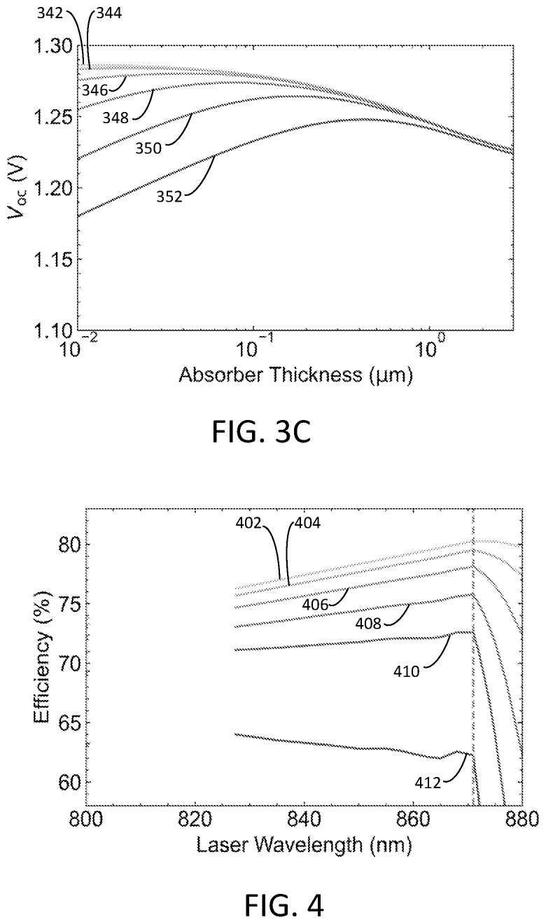

FIG. 4 shows PPC efficiency as a function of laser wavelength for different values of path-length enhancement X. Curves 402, 404, 406, 408, 410, and 412 correspond to path-length enhancement values X of 6000, 1200, 250, 50, 10, and 2 respectively. FIG. 4 shows that for path-length enhancement in 10-1200x, the optimal laser wavelength becomes the material bandgap, 871 nm. This finding fixes the wavelength of interest at 870 nm for the optical simulations (leaving 1 nm of bandwidth for a laser). The results show that increasing levels of path-length enhancement yield substantially higher optimal efficiencies. For a path-length enhancement from 2x to 10x, the maximum efficiency increases by 8.4% absolute. A PPC can receive more J_{sc} gains from absorption enhancement than a solar cell, because for the PPC all the monochromatic light lies near the bandgap where absorption is limited. Light trapping also allows for higher V_{oc} by enabling thinning of the absorber, reducing bulk recombination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A photovoltaic cell comprising:
a front layer;
a rear layer; and
an absorber layer between the front layer and the rear layer,
wherein the front layer, the rear layer, or both comprises a multiplicity of nanostructures, each nanostructure having dimensions in a range of about 1 nm to about 1000 nm.

2. The photovoltaic cell of claim 1, wherein an outer surface of the front layer comprises the multiplicity of nanostructures.

3. The photovoltaic cell of claim 1, wherein the multiplicity of nanostructures is embedded in a material having an index of refraction that differs from an index of refraction of the nanostructures.

4. The photovoltaic cell of claim 1, wherein the multiplicity of nanostructures is in a shape of cones, pyramids, bars, crosses, or any combination thereof

5. The photovoltaic cell of claim 1, wherein a spacing between the multiplicity of nanostructures is uniform.

6. The photovoltaic cell of claim 1, wherein the multiplicity of nanostructures is arranged in a periodic 1-, 2-, or 3-dimensional array.

7. The photovoltaic cell of claim 1, wherein the multiplicity of nanostructures is configured to refract, reflect, or diffract incident light into a range of propagation angles to alter light trapping, optical path length, photogeneration of electron and hole charge carriers, and photocurrent production in the photovoltaic cell.

8. The photovoltaic cell of claim 1, wherein a spacing between the multiplicity of nanostructures is less than a wavelength of light to be diffracted by the multiplicity of nanostructures.

9. The photovoltaic cell of claim 1, wherein a size of the multiplicity of nanostructures is less than a wavelength of light to be diffracted by the multiplicity of nanostructures.

10. The photovoltaic cell of claim 1, wherein the multiplicity of nanostructures comprises amorphous silicon (a-Si), GaAs, AlInP, AlGaAs, GaInP, InGaAs, Ge, Si, AlP, InN, ZnO, GaP, CdSe, ZnTe, SiC (amorphous or crystalline), TiO₂, CdTe.

11. The photovoltaic cell of claim 1, wherein the multiplicity of nanostructures comprises a perovskite.

12. The photovoltaic cell of claim 11, wherein the perovskite comprises CH₃NH₃Pb(Cl, Br,I)₃.

13. The photovoltaic cell of claim 1, wherein the multiplicity of nanostructures comprises GaN, ZnSe, ZnS, CdS, Ta₂O₅, Al₂O₃, AlN, MgO, ZnCdO, ITO, SU-8, SiNₓ, SiO₂, or MgF₂.

14. The photovoltaic cell of claim 1, wherein the multiplicity of nanostructures comprises an organic semiconductor.

15. The photovoltaic cell of claim 14, wherein the organic semiconductor comprises C₂₂H₁₄.

16. The photovoltaic cell of claim 1, wherein the multiplicity of nanostructures comprises an organic polymer.

17. The photovoltaic cell of claim 16, wherein the organic polymer comprises poly(methyl methacrylate) or PEDOT:PSS.

18. The photovoltaic cell of claim 1, wherein the multiplicity of nanostructures comprises a diffractive grating.

19. The photovoltaic cell of claim 1, wherein the rear layer is a reflective layer.

20. The photovoltaic cell of claim 1, further comprising an angular selective filter on the front layer.

21. A device comprising the photovoltaic cell of claim 1.

22. The photovoltaic cell of claim 1, wherein the multiplicity of nanostructures is configured to minimally refract, reflect, or diffract incident light having wavelengths with a photon energy below a bandgap energy of the photovoltaic cell.

23. The photovoltaic cell of claim 22, wherein the incident light is infrared light.

24. The photovoltaic cell of claim 1, further comprising a multiplicity of microstructures configured to couple infrared light into and out of the photovoltaic cell, wherein each microstructure has dimensions in a range of about 0.7 um to about 1000 um.

25. A photovoltaic cell comprising:
a front layer;
a rear layer; and
an absorber layer between the front layer and the rear layer,
wherein the front layer, the rear layer, or both comprises a multiplicity of structures, each structure having dimensions in a range of about 1 nm to about 1000 μm.

26. The photovoltaic cell of claim 25, wherein each structure has a dimension in a range of about 1 nm to about 20 μm.

27. The photovoltaic cell of claim 26, wherein each structure has a dimension in a range of about 50 nm to about 1 μm.
